(19) United States
(12) Patent Application Publication
(10) Pub. No.: US 2016/0028978 A1
(43) Pub. Date: Jan. 28, 2016

(54) IMAGING APPARATUS

(71) Applicant: Panasonic Intellectual Property Management Co., Ltd., Osaka (JP)

(72) Inventors: TIANYI YU, Osaka (JP); HISAKAZU HITOMI, Osaka (JP)

(21) Appl. No.: 14/877,804

(22) Filed: Oct. 7, 2015

Related U.S. Application Data
(63) Continuation of application No. PCT/JP2014/004805, filed on Sep. 18, 2014.

(30) Foreign Application Priority Data
Jan. 15, 2014 (JP) 2014-004744

(51) Int. Cl. H04N 5/365; H04N 5/3745; H04N 5/378

(52) U.S. Cl. CPC H04N 5/365; H04N 5/378; H04N 5/37455

(57) ABSTRACT

An imaging apparatus includes a pixel unit and an analog-to-digital (AD) converter unit which are divided into a first cluster and a second cluster. The first cluster includes a plurality of pixel columns including a first pixel column, and a plurality of AD converters corresponding to the respective pixel columns. The second cluster includes a plurality of pixel columns, a plurality of AD converters corresponding to the respective pixel columns, and an additional AD converter. The pixels of the first pixel column are coupled with both the AD converter and the additional AD converter.

### BACKGROUND

1. Technical Field

The present disclosure relates to imaging apparatuses for use in digital cameras, digital video cameras, and the like.

2. Description of the Related Art

Japanese Patent Unexamined Publication No. 2012-15587 discloses a solid-state imaging apparatus which reduces vertical streak noise. The technology disclosed in Patent Literature 1 is a technology to reduce the vertical streak noise in the solid-state imaging apparatus equipped with column-type AD converters corresponding to column pixels. The technology includes a step of correcting pixel signals in an effective image area, by using a black level signal of a pixel row in the lateral direction, with the row being located at an optical black part outside of the effective image area.

However, in the solid-state imaging apparatus according to Patent Literature 1, only disclosed is that the correction is made by a means using the signal which is read from the optical black part. For this reason, there has been a problem that, when the signal is away in level from the signal of black, its signal level is so high that the signal cannot be corrected for such a large difference corresponding to the high-level signal. To address this problem, the present disclosure is intended to provide an imaging apparatus which improves variations in outputs of the column-type AD converters and, more particularly, an imaging apparatus capable of improving vertical streaks attributed to the variations.

### SUMMARY

An imaging apparatus according to the present disclosure includes a plurality of pixels disposed two-dimensionally, a first analog-to-digital (AD) converter, and an additional AD converter. The plurality of pixels outputs pixel signals having undergone photoelectric conversion. The first AD converter is coupled with the outputs of pixels of a first pixel column and converts the signal of the outputs into a digital signal, with the pixels being included in the plurality of the pixels. The additional AD converter is coupled with the outputs of the pixels of the first pixel column.

The imaging apparatus according to the present disclosure is effective in suppressing the variations the in outputs of column-type AD converters. In particular, the imaging apparatus is advantageous for an improvement of vertical streaks attributed to the variations in the outputs of the column-type AD converters.

### BRIEF DESCRIPTION OF DRAWINGS

FIG. 1 is a block diagram of a configuration of an imaging element according to a first embodiment;

FIG. 2 is a block diagram of a general configuration of an imaging apparatus according to the first embodiment;

FIG. 3 is a pixel circuit diagram of the imaging apparatus according to the first embodiment;

FIG. 4 is a block diagram of a configuration of an AD converter of the imaging apparatus according to the first embodiment;

FIG. 5 is a block diagram of a general configuration of an imaging apparatus which employs the imaging apparatus according to the first embodiment;

FIG. 6 is a block diagram of a configuration of an imaging element according to a modified example of the first embodiment;

FIG. 7 is a block diagram of a configuration of an imaging element according to a second embodiment;

FIG. 8 is a block diagram of a configuration of an imaging element according to a third embodiment;

FIG. 9 is a pixel circuit diagram of the imaging element according to the third embodiment;

FIG. 10 is a block diagram of a configuration of clusters and a correction processing circuit, according to a fourth embodiment; and

FIG. 11 is a block diagram of a configuration of clusters and a correction processing circuit, according to a fifth embodiment.

### DETAILED DESCRIPTION

Hereinafter, detailed descriptions of embodiments will be made with reference to the accompanying drawings as deemed appropriate. However, descriptions in more detail than necessary will sometimes be omitted. For example, detailed descriptions of well-known items and duplicate descriptions of substantially the same configuration will sometimes be omitted, for the sake of brevity and easy understanding by those skilled in the art. It is noted that the present inventors provide the accompanying drawings and the following descriptions so as to facilitate fully understanding of the present disclosure by those skilled in the art. Note that the accompanying drawings and the following descriptions are presented to facilitate fully understanding of the present disclosure by those skilled in the art, and are not intended to impose any limitations on the subject matter described in the appended claims.

### First Exemplary Embodiment

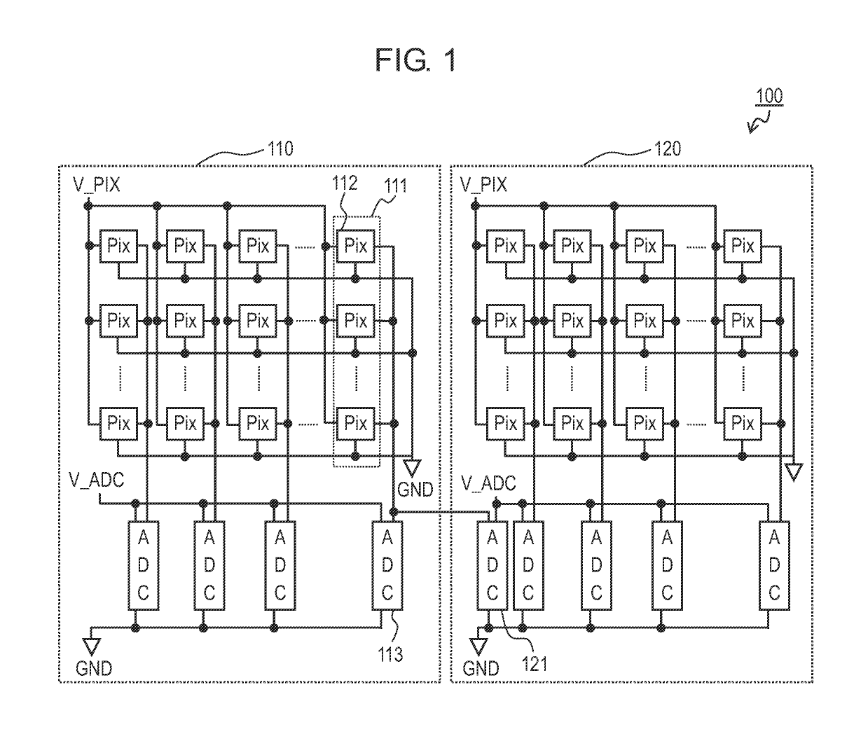

Hereinafter, a first embodiment will be described with reference to FIGS. 1 to 5.

### [1-1. Configuration]

FIG. 1 is a block diagram of a configuration of imaging element 100 according to the first embodiment of the technology disclosed herein. The embodiment employs AD converters which are column-type AD converters corresponding to respective column pixels.

As shown in FIG. 1, imaging element 100 according to the first embodiment includes a plurality of pixels 112 arranged in a matrix, and column-type analog-to-digital converters 113 (each referred to simply as AD converter or ADC, hereinafter) respectively corresponding to the columns of the matrix of pixels 112. Any one of the columns of the matrix of pixels 112 is pixel column 111.

The pluralities of pixels 112 and ADC 113 are divided into two clusters, i.e. first cluster 110 and second cluster 120. Here, the cluster is defined as a set of the pixels of the plurality of the columns and the plurality of the AD converters corresponding respectively to the plurality of the columns. Specifically, the pixels or AD converters in each of the clusters have common characteristics including a close-proximity arrangement in their layout, a common power supply (V_ADC, in FIG. 1), and a common GND, for example. Moreover, a clock may be commonly used among the AD converters in each of the clusters. Here, the words of “common” and “commonly” are used herein to mean the situation where the power supply, GND, and/or clock is distributed to each cluster from a respective single source on a cluster basis; the thus-distributed power supply, GND, and/or clock is wired for a common use within the each cluster. The number of the plurality of the columns configuring the cluster is determined by constraints in view of a circuit, their layout, and the like. For example, the number of the columns is expected to be 64 to 256. However, the number is not always restricted to be a power of two. Moreover, in the case where the whole arrangement is longitudinally divided in two, the number can be expected to be a larger value, e.g. 960, 1920, or the like.

FIG. 1 shows the case where a total rectangular area is laterally divided in two, a left and right rectangular areas, i.e. first cluster 110 and second cluster 120. In this case, the power and GND are each distributed and supplied to each of the clusters where the supplied power and GND are commonly used in the each cluster.

In the embodiment, the description is made using the case where one area is divided into two clusters, i.e. first cluster 110 and second cluster 120. However, it is also possible to divide the area into three or more clusters, with the clusters being parallel and disposed in a lateral row, i.e. first cluster 110, second cluster 120, and the next one, in this order in the row.

First cluster 110 includes a plurality of the pixel columns including first pixel column 111 and a plurality of the AD converters including first AD converter 113. Pixel column 111 includes a plurality of the pixels including first pixel 112. Second cluster 120 includes a plurality of the pixel columns and a plurality of the AD converters including additional AD converter 121.

In first cluster 110, the pixels of the plurality of the pixel columns including first pixel column 111 are respectively coupled with the plurality of the AD converters including first AD converter 113. In second cluster 120, the pixels of the plurality of the pixel columns are respectively coupled with the plurality of the AD converters excluding additional AD converter 121. Moreover, outputs of the pixels of first pixel column 111 are inputted to both AD converter 113 and additional AD converter 121. In this case, viewed from the output sides of the pixels of first pixel column 111, AD converter 113 and additional AD converter 121 are electrically coupled in parallel with each other.

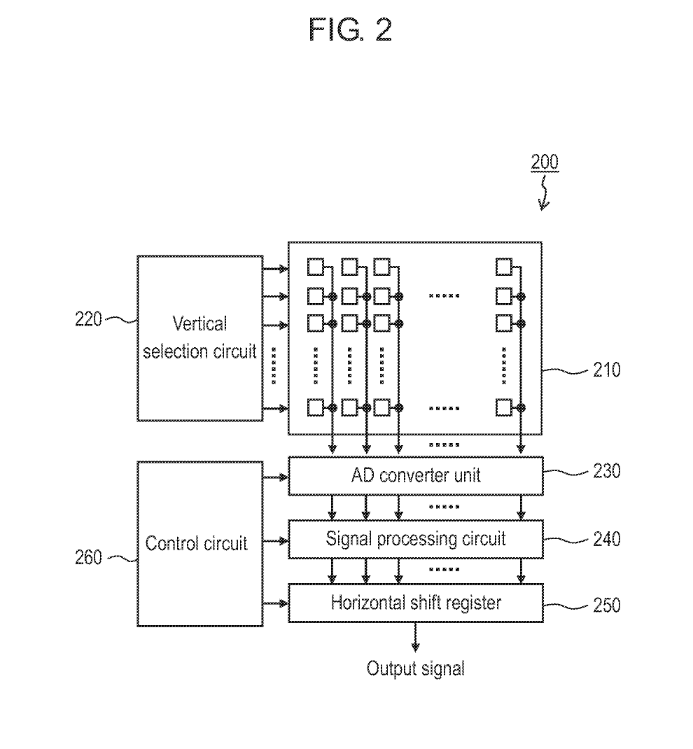

FIG. 2 is a view of a general configuration of imaging apparatus 200 using imaging element 100 (a CMOS image sensor, in this case) in FIG. 1. Pixel unit 210 and AD converter unit 230 in FIG. 2 correspond to imaging element 100 in FIG. 1. In this case, imaging element 100 is formed as a semiconductor device. Imaging apparatus 200 including imaging element 100 is formed as a semiconductor apparatus. The semiconductor apparatus may be configured with either a one-piece semiconductor chip or a plurality of semiconductor chips.

Imaging apparatus 200 is configured with pixel unit 210, vertical selection circuit 220, AD converter unit 230, signal processing circuit 240, horizontal shift register 250, and control circuit 260. Pixel unit 210 is configured with the plurality of pixels 112 that are disposed two-dimensionally in the horizontal and vertical directions, as described using FIG. 1.

The output of vertical selection circuit 220 is inputted to pixel unit 210 to select the vertical positions of the pixels. The pixel outputs of thus-selected one horizontal line are inputted to AD converter unit 230, every horizontal period. The outputs of AD converter unit 230, i.e. the data from the one horizontal line, are inputted every horizontal period to signal processing circuit 240 that performs digital signal processing. The outputs of signal processing circuit 240, i.e. the data from the one horizontal line, are inputted every horizontal period to horizontal shift register 250. After the data from the one horizontal line are temporally inputted to and stored in horizontal shift register 250, the shift register outputs the stored data as an output of imaging apparatus 200, either every one pixel or every plurality of the pixels.

Control circuit 260 performs control so that the pixel data are output every one horizontal line, via AD converter unit 230, signal processing circuit 240, and horizontal shift register 250.

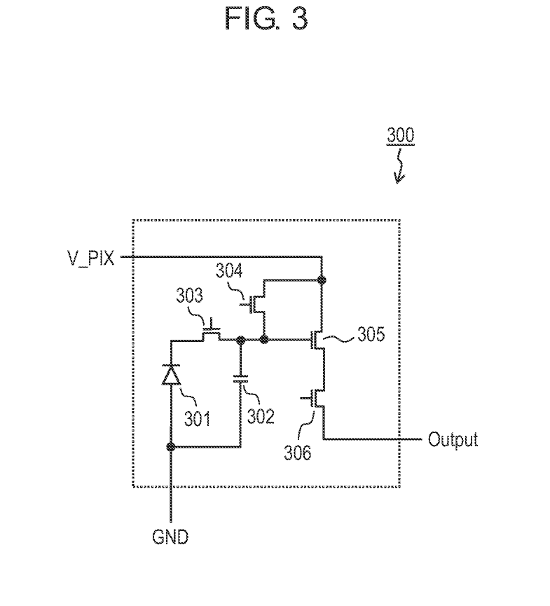

Next, FIG. 3 shows pixel circuit 300, an example of a pixel circuit of pixel 112 in FIG. 1. Pixel circuit 300 is configured with photodiode 301, floating diffusion (FD) 302, vertical selection transistor 303, reset transistor 304, source follower transistor 305, and horizontal selection transistor 306. Photodiode 301 is a photoelectric conversion element which converts light from a subject into a signal charge. The signal charge is converted into a signal voltage by FD 302. The signal voltage is inputted to source follower transistor 305, in accordance with a vertical selection signal that is inputted to vertical selection transistor 303. Reset transistor 304 is a transistor to perform initialization in accordance with a reset signal inputted from the vertical selection circuit. Source follower transistor 305 is a transistor to output the signal voltage, which is converted to the voltage by FD 302, to a vertical signal line in accordance with a horizontal selection signal inputted to horizontal selection transistor 306.

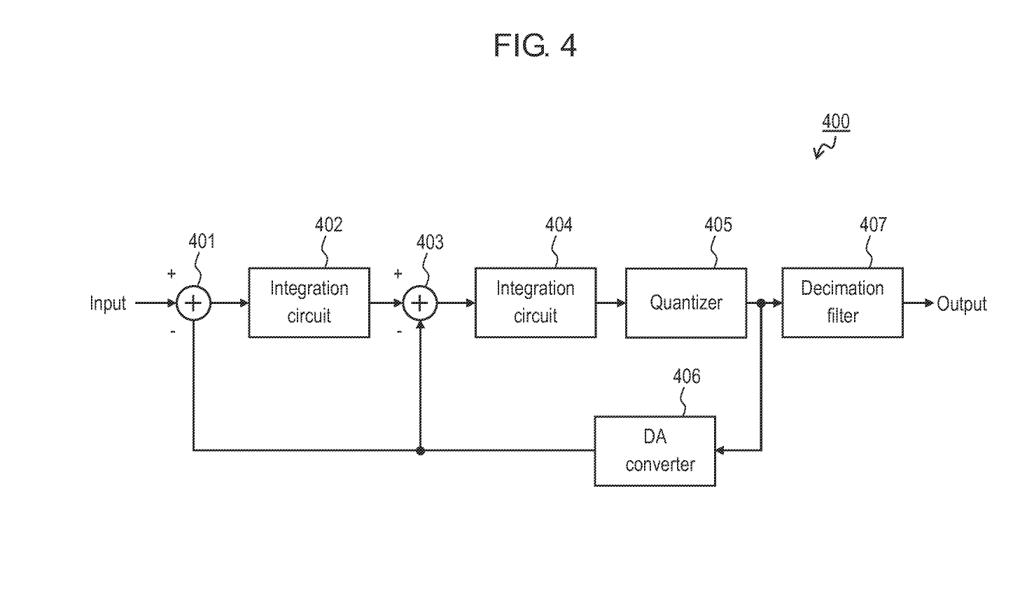

FIG. 4 shows an example of a configuration of the AD converter according to the embodiment. In the embodiment, a second-order delta-sigma AD converter is used as an example. AD converter 400 converts the analog voltage output from the pixel into a digital signal. AD converter 400 is configured with adders 401 and 403, integration circuits 402 and 404, quantizer 405, and digital-to-analog (DA) converter 406. The analog voltage output from the pixel is inputted to AD converter 400. Then, this inputted analog signal is output as a digital signal, via adder 401, integration circuit 402, adder 403, integration circuit 404, quantizer 405, and decimation filter 407. The output of quantizer 405 is converted to an analog signal by DA converter 406. The converted analog signal is then sign-inverted, fed back to adders 401 and 403 where it is added to the respective signals.

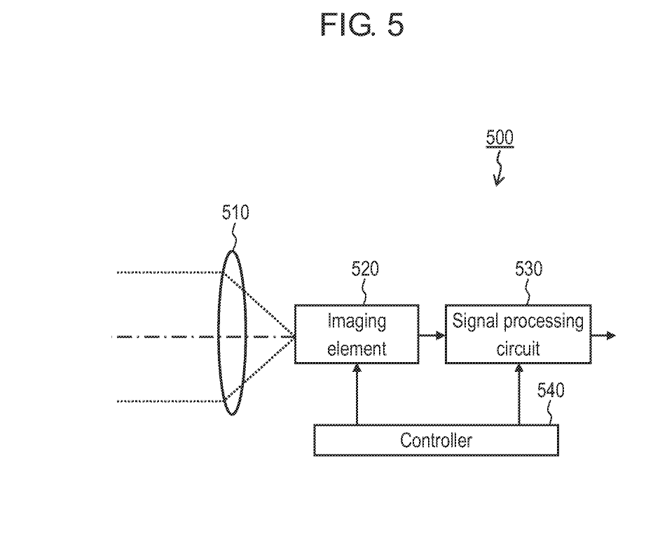

FIG. 5 is a block diagram of a general configuration of an imaging apparatus which employs imaging apparatus 200 shown in FIG. 2. Imaging apparatus 500 is configured with an optical system including lens 510, imaging element 520, signal processing circuit 530, controller 540, and the like.

Lens 510 focuses image light from a subject onto an imaging surface of imaging element 520 to form an optical image thereon. Imaging element 520 converts the image light, which is focused on the imaging surface by lens 510, into an electrical signal on a unit of pixel basis, and then outputs the resulting image signal.

Signal processing circuit 530 applies various kinds of image processing to the image data that is output from imaging element 520. The signal processing circuit applies the following processes to the image data that is output from imaging element 520: That is, the processes include white balance adjustment, gamma correction, YC conversion, electronic zoom, and compression, for example. It is noted, however, that signal processing circuit 530 may perform either all of the image processes described above or some of them.

Controller 540 controls imaging element 520 and signal processing circuit 530 in accordance with a computer program provided by software or firmware.

### [1-2. Operation]

Operations of thus-configured imaging element 100 in FIG. 1 and thus-configured imaging apparatus 200 in FIG. 2 will be described, hereinafter.

The cluster is the set of the pixels of the plurality of the columns and the plurality of the AD converters respectively corresponding to the plurality of the columns, as described above. The pixels or AD converters in each of the clusters have common features including a close-proximity arrangement in their layout, a common power supply, and a common GND, for example.

For this reason, in one given cluster, variations are small in characteristics among the pixels of the columns and among the AD converters. Hereinafter, for convenience of explanation, in the one given cluster, it is assumed that such variations are so negligibly small, among the pixels of the columns and among the AD converters, that their characteristics are equivalent to each other.

In contrast, between different clusters, variations are large in characteristics of the pixels of the columns and of the AD converters. For this reason, between the different clusters, it is necessary to suppress such variations in characteristics of the pixels of the columns and of the AD converters. Given these factors, a method will be described herein for detecting such variations in characteristics of the AD converters between the different clusters.

As described above, both AD converter 113 and additional AD converter 121 are electrically coupled in parallel with the output of the pixels of pixel column 111 that is common to the both converters. The pixels of pixel column 111 are selected sequentially from upper one, in accordance with output timing of vertical selection circuit 220. First, pixel 112 disposed at the top of pixel column 111 is selected. The output of pixel 112 is then output to the vertical signal line that couples between AD converter 113 and the pixels of pixel column 111. In this manner subsequently, the output of the pixel sequentially selected every horizontal period is output to the vertical signal line that couples between AD converter 113 and the pixels of pixel column 111.

As described above, in the first embodiment, the output signal of the same pixel column 111 is output to both AD converter 113 and additional AD converter 121. In this configuration, AD converter 113 and additional AD converter 121 each receive the same analog input. If the digital outputs of these converters are different from each other, such a difference can be considered to be due to the variations in characteristics between AD converter 113 and additional AD converter 121. Because the characteristics of the AD converters in each of the cluster concerned can be treated as identical ones, the characteristics of AD converter 113 can represent those of the AD converters in cluster 110. In the same manner, the characteristics of additional AD converter 121 can represent those of the AD converters in second cluster 120.

As can be seen from the above description, the detection of the difference in the digital output values between AD converter 113 and additional AD converter 121, allows detection of the variations in characteristics of the AD converters between first cluster 110 and second cluster 120.

Moreover, the detection of the differences in characteristics of the AD converters between the two adjacent clusters makes it possible to perform appropriate correction for reducing such characteristic differences, which allows a reduction in the variations in characteristics of the AD converters.

### [1-3. Advantage and Others]

Both AD converter 113 and additional AD converter 121 are inputted with the output of the pixel selected sequentially from upper one, thereby detecting the differences in characteristics between the converters. Then, the result of the detection is output. The process described above is performed at the same timing at which the usual pixel outputs. With this configuration, there is no need for a test period, for example, which is set for every frame, at any timing within the frame. This allows the real-time detection of the characteristic differences without any time slot for such a test period, even in a case of the frame rate being increased due to the increased number of the pixels. This results in improved usefulness of the configuration. Moreover, in a method in which the difference is detected and corrected at a specific point in time of an inspection process and the like, the correction can be accurately performed even if the difference data would vary due to subsequent time-based deterioration and/or to changes of the condition of temperature and the like.

Moreover, the output of the detection of the characteristic differences between the AD converters is a value which is determined by detecting the actually-inputted signal. Accordingly, even if the level of the input signal is either low or high, the detection of the characteristic differences can be performed between the AD converters, commensurately with the level whatever the level is. With this configuration, the following problem posed by conventional technologies is difficult to occur. Conventionally, the difference has been detected at a black level, and used to perform the correction. Unfortunately, such a thus-detected difference will vary under a different detection condition apart from that of the black level, which results in an inaccurate correction.

It is possible to classify the characteristic differences between the AD converters in two categories, i.e. an offset difference and a gain difference. For example, in the case where the characteristic difference is detected at a black level, the detected difference can be considered as the offset difference. In the case of the gain differences being zero, the correction can be performed by correcting only the offset differences because the characteristic difference is constant independently of the level. However, in the case of the gain difference existing, the correction is not sufficiently performed by correcting only the offset difference because the characteristic difference varies depending on the level. In the first embodiment, for an actual signal level, the characteristic difference can be detected by using these two AD converters. As a result, the detected difference is then equal to a sum of the offset difference and the gain difference, in accordance with the signal level. With the configuration described above, the differences in characteristics between the AD converters can be detected with high accuracy in accordance with the level of the input signal. Use of the result of the highly accurate detection allows a reduction in vertical streaks attributed to the variations in characteristics between the AD converters.

### Modified Example of First Exemplary Embodiment

A modified example of the first embodiment is one in which a configuration is added to that of the first embodiment so as to improve degradation in the characteristics caused by the addition of the additional AD converter.

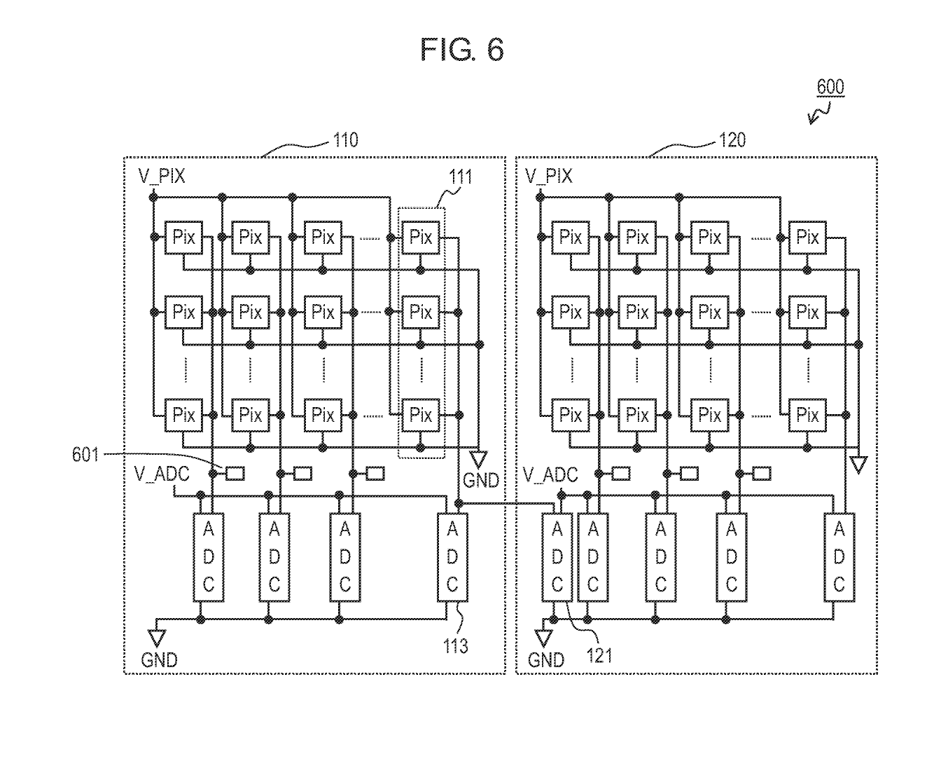

FIG. 6 is a block diagram of a configuration of imaging element 600 which includes elements of loads 601. The configuration except for the elements is the same as that of FIG. 1 and that of the first embodiment; therefore, drawings and descriptions thereof are appropriately omitted. In the first embodiment, the output of the pixels of pixel column 111 is coupled with the two AD converters, i.e. AD converter 113 and additional AD converter 121. Therefore, pixel column 111 is subjected to increased load capacity in comparison with the other pixel columns. The modified example of the first embodiment is configured such that a load is added to each of the wirings that couple between the pixels of the pixel columns except for pixel column 111 and the respective AD converters, in imaging element 100 shown in FIG. 1. This configuration makes it possible to cause the load capacity on the output of the pixels of pixel column 111 to equal that on the output of the pixels of each of the other columns. With this configuration, it is possible to prevent the occurrence of the differences in input between the AD converters.

### Second Exemplary Embodiment

Hereinafter, a second embodiment will be described with reference to FIG. 7 and FIGS. 2 to 5. It is noted, however, that the configurations shown in FIGS. 2 to 5 are the same as those described in the first embodiment; therefore, descriptions thereof will be omitted.

### [2-1. Configuration]

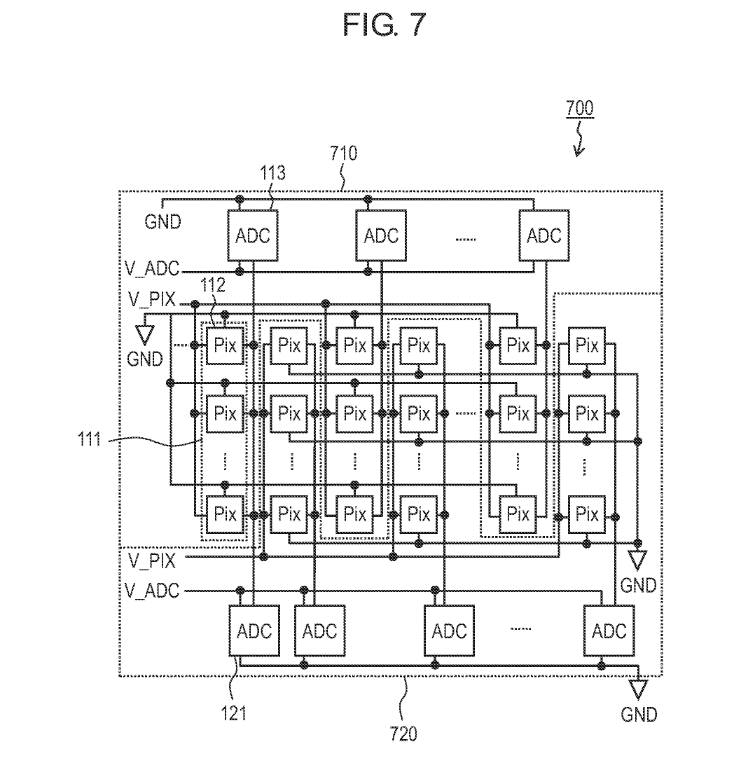

FIG. 7 is a block diagram illustrating imaging element 700 according to the second embodiment. In imaging element 700, a set of the pixels and the AD converters is divided into two clusters, i.e. first cluster 710 and second cluster 720.

In imaging element 700 according to the second embodiment, both first cluster 710 and second cluster 720 are disposed in a total rectangular area in such a way that the pixel unit with the plurality of pixels 112 is longitudinally divided in two in a two-combs-engaging manner, in the up and down directions. The AD converters are disposed at both an upper and a lower portion of the pixel unit. Although the pixel unit is disposed as a whole in the total rectangular area, the pixel unit is configured such that each of the columns is coupled with the corresponding one of the AD converters disposed at either the upper or the lower portion, in an alternating manner. The power supply and GND are distributed to each of the clusters. The distributed power supply and GND are commonly used in the each of the clusters. It is noted, however, that the words of “upper” and “lower” of the pixel unit used herein respectively indicate the up and down directions of the columns of the matrix configured with the plurality of pixels 112.

Concerning the configuration of the pixels and the AD converters of imaging element 700, the description is made using the case where the set is longitudinally divided into the two clusters, i.e. cluster 710 and cluster 720. However, another configuration is also possible in which the set is divided into four clusters. Every two of the four clusters configure a rectangular area (in total, two rectangular areas) which is the same as the area configured with cluster 710 and cluster 720. Such two rectangular areas are disposed in parallel side by side.

Cluster 710 is the same as the corresponding cluster of the first embodiment, in terms of the relationship between the plurality of the pixel columns including pixel column 111 and the plurality of the AD converters including AD converter 113.

Likewise, cluster 720 is the same as the corresponding cluster of the first embodiment, in terms of the relationship between the plurality of the pixel columns and the plurality of the AD converters including first additional AD converter 121.

The configuration (imaging element 700) of the pixels and the AD converters shown in FIG. 7 corresponds to that of pixel unit 210 and AD converter unit 230 shown in FIG. 2.

The configuration of pixels 112 shown in FIG. 7 is the same as that shown in FIG. 3. The configuration of AD converter 113 shown in FIG. 7 is the same as that shown in FIG. 4. The block diagram of a general configuration of the imaging apparatus according to the embodiment is the same as that shown in FIG. 5.

### [2-2. Operation]

Although the cluster configuration is different from that according to the first embodiment, a fundamental operation of the configuration is the same as that according to the first embodiment.

### [2-3. Advantage and Others]

As in the case of the first embodiment, the differences in characteristics of the AD converters between the different clusters can be detected with high accuracy. Use of the result of the detection allows a reduction in a harmful effect attributed to the variations in characteristics of the AD converters between the different clusters. In the second embodiment, the harmful effect attributed to the variations in characteristics of the AD converters between the different clusters will cause vertical streaks which appear for every other column because the set is longitudinally divided into the two clusters in a two-combs-engaging manner in the up and down directions. Such vertical streaks can be improved in accordance with the embodiment.

### Third Exemplary Embodiment

Hereinafter, a third embodiment will be described with reference to FIG. 8 and FIGS. 2 to 5. It is noted, however, that each of the configurations shown in FIGS. 2 to 5 is the same as that described in the first embodiment; therefore, description thereof will be omitted.

### [3-1. Configuration]

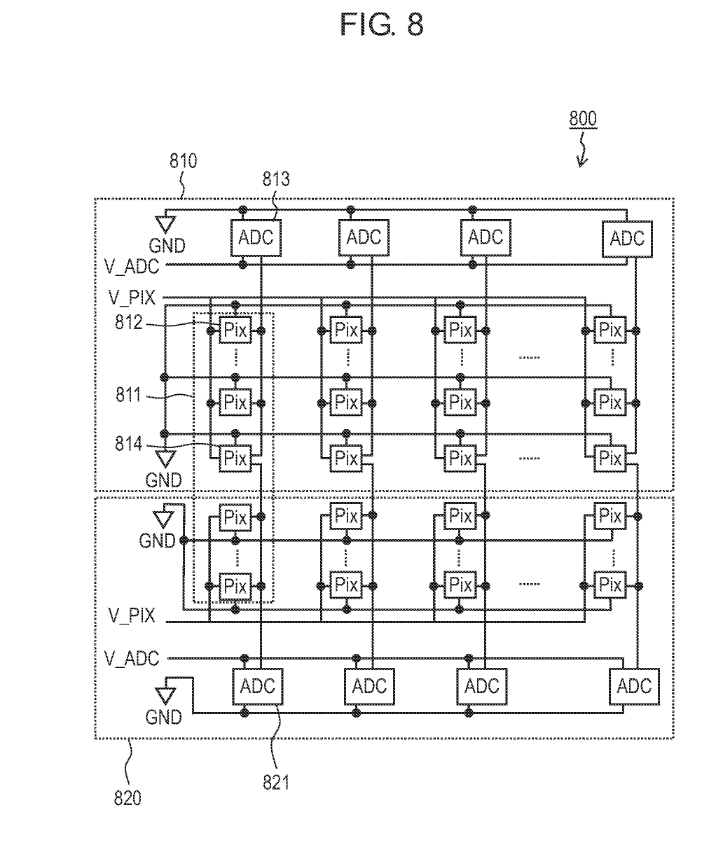

FIG. 8 is a block diagram of a configuration of imaging element 800 according to the third embodiment. In imaging element 800 according to the third embodiment, the pixels and the AD converters are divided into two clusters, an upper and a lower one, i.e. cluster 810 and cluster 820.

In imaging element 800 according to the third embodiment, cluster 810 and cluster 820 are in rectangular areas which are formed by dividing a total rectangular area longitudinally in two. The AD converters are disposed at both top and bottom portions of the element. The pixels are disposed as a whole in the total rectangular area, and divided longitudinally into two sets, with the pixels located on the upper side being coupled with the top AD converters while the pixels located on the lower side being coupled with the bottom AD converters. The power and GND are each distributed and supplied to each of the clusters where the supplied power and GND are commonly used in the each cluster. It is noted, however, that the words of “upper” and “lower” used herein respectively indicate the up and down directions of the columns of the matrix configured with the plurality of pixels 112.

Concerning the configuration of the pixels and the AD converters of imaging element 800, the description is made using the case where the cluster is longitudinally divided into two clusters, i.e. cluster 810 and cluster 820. However, another configuration is also possible in which the cluster is divided into four clusters. Every two of the clusters configure a rectangular area (in total, two rectangular areas) which is the same as that configured with cluster 810 and cluster 820. Such two rectangular areas are disposed in parallel side by side.

Cluster 810 includes the plurality of the upper-row pixels including specific pixel 814 and the plurality of the upper-row AD converters including AD converter 813. Cluster 820 includes the plurality of the lower-row pixels and the plurality of the lower-row AD converters including AD converter 821.

Pixel column 811 includes a plurality of the upper-row pixels including pixel 812, specific pixel 814, and a plurality of the lower-row pixels. Of pixel column 811, the plurality of the upper-row pixels including specific pixel 814 are coupled with AD converter 813. Of pixel column 811, the plurality of the lower-row pixels and specific pixel 814 are coupled with AD converter 821. Likewise, in each of the pixel columns other than pixel column 811, a plurality of the upper-row pixels is coupled with the corresponding upper-row AD converter, while a specific pixel and a plurality of the lower-row pixels are coupled with the corresponding lower-row AD converter. In this case, viewed from the output side of specific pixel 814, AD converter 813 and AD converter 821 are electrically coupled in parallel with each other.

Here, the specific pixels may be any ones of the pixels; however, the specific pixels in this case shown in FIG. 8 are ones that are disposed in the lowest-row of the pixels of cluster 810, with the lowest-row being on a line in contact with the border with cluster 820. The specific pixel of each of the columns is coupled with both the corresponding upper-row AD converter and the corresponding lower-row AD converter. For this reason, the output of the specific pixel is subjected to increased load capacity relative to the usual pixels.

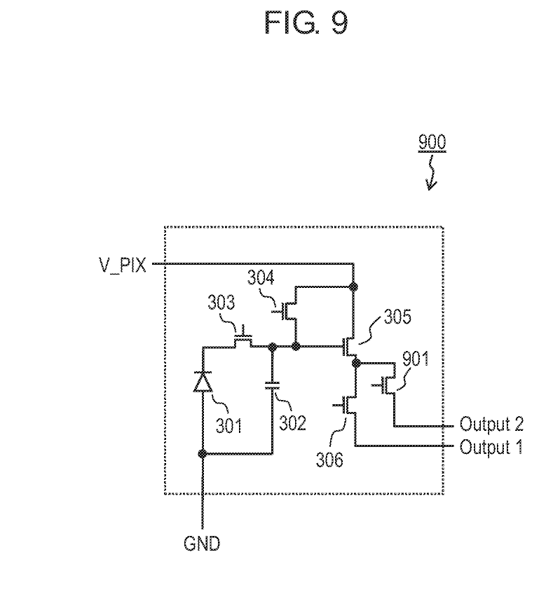

An example of a configuration of specific pixel 814 is pixel circuit 900 shown in FIG. 9. Pixel circuit 900 is different from pixel circuit 300 in that the circuit further includes vertical selection transistor 901 and has dual output lines, i.e. output 1 and output 2. Output 1 is coupled with upper-row AD converter 813, while output 2 is coupled with lower-row AD converter 821. With this configuration, the load capacity viewed from output 1 can be made approximately equal to that viewed from output 2.

It is noted, however, that, in cases where the influence of the increase in load capacity does not matter or a higher priority is given to a uniformed configuration of the pixels, the specific pixel may be configured in the same manner as for the usual pixels, with the output thereof being coupled with both the upper and lower AD converters.

The configuration of each of the usual pixels including pixel 812 is the same as that shown in FIG. 3. The usual pixels as referred herein are the pixels except for the specific pixels.

Imaging element 800 according to the third embodiment corresponds to pixel unit 210 and AD converter unit 230 shown in FIG. 2. Although the AD converters in FIG. 8 are longitudinally divided into the upper and lower ones, the sum of the upper and lower AD converters corresponds to AD converter unit 230, with the outputs of all of the AD converters being inputted to signal processing circuit 240. The remaining part of the configuration is the same as that described in the first embodiment.

### [3-2. Operation]

Hereinafter, a description will be made regarding the operation of imaging element 800 configured as described above according to the third embodiment shown in FIG. 8, and the operation of imaging apparatus 200 shown in FIG. 2.

As described above, the pixels are longitudinally divided in two, i.e. cluster 810 and cluster 820. The power and GND are each distributed and supplied to each of the clusters where the supplied power and GND are commonly used in the each cluster. In the each of cluster 810 and cluster 820, the pixels or AD converters in the each cluster have common features including a close-proximity arrangement in their layout, a common power supply, and a common GND, for example. For this reason, in one given cluster, variations in characteristics are small among the pixels of the pixel columns and among the AD converters. Hereinafter, for convenience of explanation, in the one given cluster, it is assumed that such variations are so negligibly small, among the pixels of the pixel columns and among the AD converters, that their characteristics are equivalent to each other.

In contrast, between different clusters, the variations are large in characteristics of the pixels of the columns and of the AD converters. For this reason, between the different clusters, it is necessary to suppress such variations in characteristics of the pixels of the columns and of the AD converters. Given these factors, a method will be described herein for detecting such variations in characteristics of the AD converters between the different clusters.

First, the description is made regarding the operation of pixel column 811.

As described above, both AD converter 813 and AD converter 821 are coupled with the output of common specific pixel 814. The pixels are selected sequentially basically from upper ones in accordance with output timing of vertical selection circuit 220. In the configuration (imaging element 800) of the pixels and AD converters shown in FIG. 8, the cluster is longitudinally divided into the upper and lower clusters. Concurrently in both the clusters, the pixels of each of the clusters are selected sequentially from upper ones, and the outputs of the selected pixels are inputted to the corresponding vertical signal lines, and then inputted to the corresponding ones of AD converters 813 and AD converters 821.

There is no special constraint on read timing of specific pixel 814, in comparison with read timing of the usual pixels. In this description, however, the read timing of the specific pixel is exemplarily set at a time after the reading of all the usual pixels has been completed. For example, the description is made using a case where one column consists of 1080 pixels. Because the set of the pixels is longitudinally divided in two, pixel column 811 is configured with both 540 pixels on the lower side and 540 pixels including the specific pixel on the upper side. In this pixel column, the 540 pixels in each of the upper and lower clusters are read sequentially from upper one. After the usual reading of the 540 pixels in the each of the upper and lower clusters is completed at the 540th timing from the first timing, specific pixel 814 is read at the 541th timing simultaneously by both the upper and lower AD converters. After that, a difference is detected between the output digital values of AD converter 813 and AD converter 821, with the output digital values being separately obtained, by the AD converters, through analog-to-digital conversions of the output of specific pixel 814.

As described above, the operation of pixel column 811 has been described which also holds for the other pixel columns.

### [3-3. Advantage and Others]

The configuration described above makes it possible to accurately detect the differences in characteristics of the AD converters between the different clusters. The differences in characteristics of the AD converters between cluster 810 and cluster 820 can be detected and the correction is performed based on the detected differences, which allows a reduction in a harmful effect attributed to the differences in characteristics of the AD converters between cluster 810 and cluster 820. Conventionally, with such a cluster configuration where a cluster is longitudinally divided into upper and lower clusters in a conventional manner, a harmful effect thereof is a horizontal streak attributed to the differences in characteristics of the AD converters between cluster 810 and cluster 820; such a horizontal streak is due to a step height between the horizontal line of the specific pixels and the next horizontal line, at the border of the clusters. Fortunately, the cluster configuration described in the third embodiment allows the improvement of the horizontal streak.

### Fourth Exemplary Embodiment

### [4-1. Configuration]

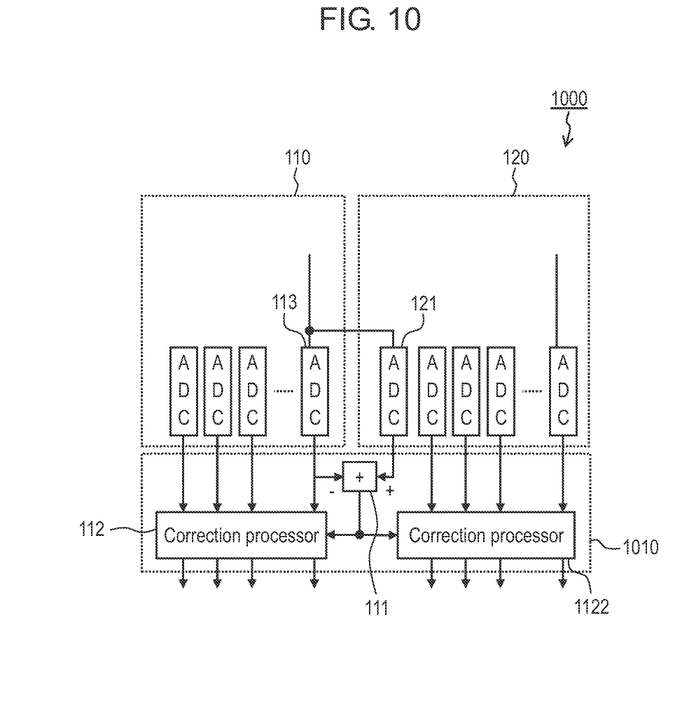

FIG. 10 is a block diagram of a configuration of clusters and a correction processing circuit of imaging element 1000 according to a fourth embodiment of the technology disclosed herein. In the fourth embodiment, a case is exemplified where a cluster is divided in two, i.e. first cluster 110 and second cluster 120.

In FIG. 10, although pixels in each of first cluster 110 and second cluster 120 are omitted, the configuration of the each is the same as those shown in FIG. 1.

The following outputs are inputted to correction processing circuit 1010. That is, the outputs of AD converter 113 and the plurality of the AD converters, all present in first cluster 110; and the outputs of first additional AD converter 121 and the plurality of the AD converters, all present in second cluster 120. Correction processing circuit 1010 includes subtracter 1111 and correction processor 1112. Both the outputs of AD converter 113 and additional AD converter 121 are inputted to subtracter 1111. The outputs of AD converter 113 and the plurality of the AD converters in first cluster 110 are inputted to correction processor 1112. The output of subtracter 1111 is inputted to both correction processor 1112 and correction processor 1122.

### [4-2. Operation]

Correction processing circuit 1010 performs the correction of differences in characteristics of the AD converters between first cluster 110 and second cluster 120. Subtracter 1111 outputs a difference value which is obtained by subtracting the output of AD converter 113 from the output of additional AD converter 121. The output of subtracter 1111 is regarded as the difference of the AD converters between first cluster 110 and second cluster 120. One-half of the difference value described above is added to each of the outputs of the plurality of the AD converters in first cluster 110, while one-half of the difference value described above is subtracted from each of the outputs of the plurality of the AD converters in second cluster 120. With this process, the level step attributed to the differences of the AD converters between the clusters can be improved.

Let “N” be the number of the AD converters excluding the additional AD converter, in each of first cluster 110 and second cluster 120. Let D1(n) (n=0 to N−1) be the output value of the AD converter in first cluster 110, D2(n) (n=0 to N−1) be the output value of the AD converter in second cluster 120, and D2a be the output value of the additional AD converter in second cluster 120. Letting Dd12 be the output value of subtracter 1111, one obtains

Dd12=D2a−D1(N−1). Eq. (4-1)

Letting D1′(n) (n=0 to N−1) be the output value of the AD converter in first cluster 110, and D2′(n) (n=0 to N−1) be the output value of the correction processor, one obtains

D1′(n)=D1(n)+Dd12×(½), Eq. (4-2)

D2′(n)=D2(n)−Dd12×(½). Eq. (4-3)

### [4-3. Advantage and Others]

Here, consider the case where the inputs into the AD converters are all equal to a certain value. For example, the AD converters each have a 10-bit output taking a value of 0 (zero) to 1023. When D1(n) (n=0 to N−1) all take the same value of 500, and D2a and D2(n) (n=0 to N−1) all take the same value of 508, it follows from Eq. (4-1) that

Dd12=508−500=8.

This value of 8 is regarded as the difference of the AD converters between the clusters.

Using Eqs. (4-2) and (4-3), one obtains

D1′(n)=500+8/2=504,

D2′(n)=508−8/2=504.

Then, D1′(n) is equal to D2′(n).

As described above, it is possible to correct the differences of the AD converters between the two clusters, thereby eliminating the vertical streaks. In the above description, the description has been made using the case where the inputs into the AD converters are all equal to a certain value. However, even in cases where the inputs into the AD converters are not equal to a certain value, it is also possible to correct the differences of the AD converters between the clusters.

### Fifth Exemplary Embodiment

### [5-1. Configuration]

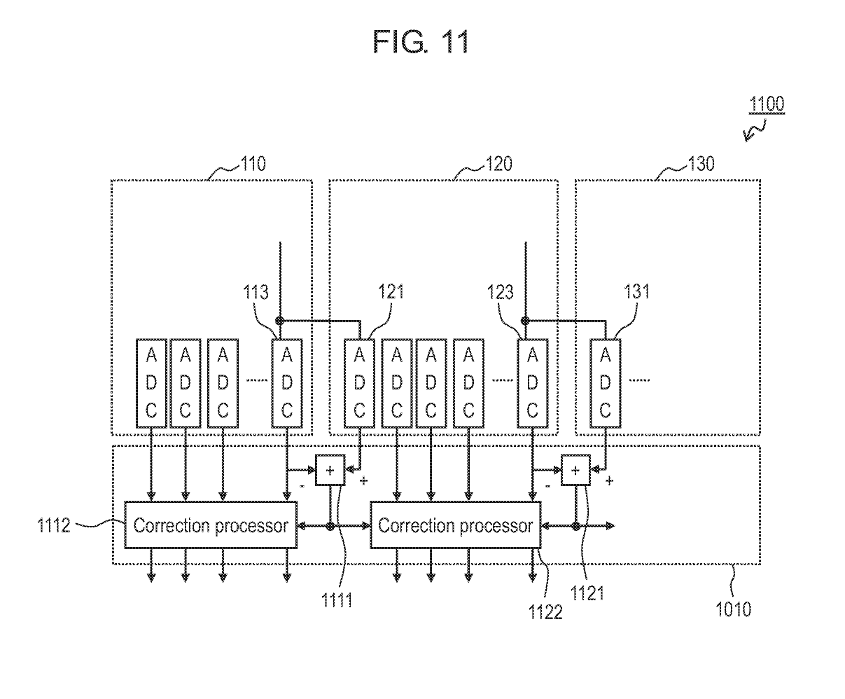

FIG. 11 is a block diagram of a configuration of clusters and a correction processing circuit of imaging element 1100 according to a fifth embodiment of the technology disclosed herein. Imaging element 1100 according to the fifth embodiment includes first cluster 110, second cluster 120, third cluster 130, and correction processing circuit 1010.

In FIG. 11, an exemplified case is shown which involves three clusters, i.e. first cluster 110, second cluster 120, and third cluster 130. Second cluster 120 is disposed at the center of the three, for example. First cluster 110 and third cluster 130 are respectively the right and left clusters disposed on both sides of second cluster 120. In the Figure of third cluster 130, only an additional AD converter is shown which is necessary for the following description; however, the third cluster has the same configuration as that of second 120. In FIG. 11, moreover, the pixels in the clusters are omitted in the same way as for FIG. 10; however, the clusters each have the same configuration of the pixels as that shown in FIG. 1.

The following outputs are inputted into correction processing circuit 1010: That is, the outputs of the plurality of the AD converters including AD converter 113, all present in first cluster 110; the outputs of additional AD converter 121 and the plurality of the AD converters, all present in second cluster 120; and the outputs of additional AD converter 131 and the plurality of the AD converters, all present in third cluster 130. Correction processing circuit 1010 includes subtracter 1111, correction processor 1112, subtracter 1121, and correction processor 1122.

The outputs of AD converter 113 and additional AD converter 121 are inputted into subtracter 1111. The outputs of AD converter 113 and the plurality of the AD converters, all present in first cluster 110, are inputted into correction processor 1112. The output of subtracter 1111 is inputted into both correction processor 1112 and correction processor 1122. The outputs of AD converter 123 and additional AD converter 131 are inputted into subtracter 1121. The output of subtracter 1121 is inputted into correction processor 1122.

### [5-2. Operation]

Correction processing circuit 1010 performs the correction of the differences of the AD converters between first cluster 110, second cluster 120, and third cluster 130. Subtracter 1111 outputs a difference value that is obtained by subtracting the output of first AD converter 113 from the output of additional AD converter 121. Subtracter 1121 outputs a difference value that is obtained by subtracting the output of AD converter 123 from the output of additional AD converter 131.

The output of subtracter 1111 is regarded as the difference of the AD converters between first cluster 110 and second cluster 120, while the output of subtracter 1121 is regarded as the difference of the AD converters between second cluster 120 and third cluster 130.

From the outputs of subtracter 1111 and subtracter 1121, it is possible to know a change caused by the differences of the AD converters between first cluster 110, second cluster 120, and third cluster 130. Then, a process similar to a low-pass filter (LPF) process is applied to reduce the change to a less and gentler one, which allows an improvement in level steps attributed to the differences of the AD converters between the clusters.

Let “N” be the number of the AD converters excluding the additional AD converter in each of the clusters. Let

D1(n)(n=0 to N−1),

D2(n) (n=0 to N−1),

D3(n) (n=0 to N−1)

be the output values of the AD converters of first cluster 110, second cluster 120, and third cluster 130, respectively.

Moreover, let D2a and D3a be the output values of the additional AD converters of second cluster 120 and third cluster 130, respectively.

Here, consider the case where the inputs into the AD converters are all equal to a certain value. If the differences occur in the first cluster and they are identical to each other, D1(n) takes the same value for any “n” number; this is true for D2(n) and D3(n) as well. Here, letting these values be Dlb, D2b, and D3b, respectively, one obtains

D1(n)=D1b (n=0 to N−1),

D2(n)=D2b (n=0 to N−1),

D3(n)=D3b (n=0 to N−1).

Moreover, the following relations can hold:

D2a=D2b,

D3a=D3b.

Letting Dd12 and Dd23 be the output values of subtracter 1111 and subtracter 1121, respectively, one obtain

Dd12=D2a−D1b, Eq. (5-1)

Dd23=D3a−D2b. Eq. (5-2)

From the above description, D1(n) and D3(n) can be expressed in terms of D2(n) as follows:

D1(n)=D2(n)−Dd12 (n=0 to N−1),

D3(n)=D2(n)+Dd23 (n=0 to N−1).

Post-correction D2(n′) can be obtained by multiplying D1(n), D2(n), and D3(n) by coefficients of ¼, 2/4, and ¼, respectively, followed by summing all the results. That is,

D2(n′)=D2(n)−(¼)×Dd12+(¼)×Dd23 (n=0 to N−1). Eq. (5-3)

In general, in addition to the three clusters described above, a plurality of clusters is additionally and successively disposed on the right side of second cluster 120, with the additional ones each having the same configuration as that of second cluster 120 shown in FIG. 11. In the above description, the illustration has been made mainly regarding the correction of second cluster 120 that is present at the center of the three clusters. For the case where four or more clusters are disposed, the correction is performed in such a manner that: A correction is performed using a set of three clusters, i.e. a left, center, and right clusters among the clusters. Such a correction is made for the center one, in the same manner as that for the three-clusters case described above. Then, another correction is performed using another set of three clusters which are chosen such that the center one to-be-corrected is shifted sequentially rightward to the next one.

Moreover, in the above description, the illustration has been made regarding the correction using the three clusters, i.e. the left, center, and right clusters. However, in the case of a large number of the clusters, the correction may be performed using a more number of the clusters present on the left and right sides of the center one to-be-corrected. For example, the correction may be performed using five clusters in total, with two clusters being preset on each of the both sides of the center one.

Furthermore, the numbers of the clusters present on the left and right sides may not necessarily be equal to each other.

### [5-3. Advantage and Others]

Here, consider the case where the inputs into the AD converters are all equal to a certain value. For example, the AD converters each have a 10-bit output taking a value of 0 (zero) to 1023. Specifically, the description is made regarding the case where D1(n) (n=0 to N−1) all take the same value of 500, D2a and D2(n) (n=0 to N−1) all take the same value of 508, and D3a and D3(n) (n=0 to N−1) all take the same value of 504. In this case, it follows from Eq. (5-3) that

D2(0=505 (n=0 to N−1).

This reduces such a large value of original D2(n) that is prominent relative to the left and right ones.

As described above, the differences of the AD converters between the clusters can be corrected to eliminate the vertical streaks. In the above description, the case has been illustrated where the inputs into the AD converters are all equal to a certain value. However, even in the case where the inputs into the AD converters are all not equal to a certain value, it is possible to correct the differences of the AD converters between the clusters.

As described above, the first to fifth embodiments have been described as examples of the technology disclosed in the present application. However, the technology disclosed herein is not limited to these embodiments, and is also applicable to embodiments that are subjected, as appropriate, to various changes and modifications, replacements, additions, omissions, and the like. Moreover, the technology disclosed herein also allows another embodiment which is configured by combining the appropriate constituent elements described above in the first to fifth embodiments.

Moreover, in the first to fifth embodiments, the descriptions have been made using the CMOS image sensor, a solid-state imaging element, as an example of the imaging means (image sensor). However, the imaging means is only required to include the column-type AD converter, and not limited to the CMOS image sensor and the solid-state imaging element.

Furthermore, because the aforementioned embodiments are used only for the exemplification of the technology disclosed herein, it is to be understood that various changes and modifications, replacements, additions, omissions, and the like may be made to the embodiments without departing from the scope of the appended claims or the scope of their equivalents.

The technology according to the present disclosure is applicable to imaging apparatuses. Specifically, the technology is applicable to imaging apparatuses for use in studio cameras, industrial-use cameras, digital still cameras, movie/video cameras, mobile cellular telephones with a function of imaging, smartphones, and the like.

What is claimed is:

1. An imaging apparatus comprising:
a plurality of pixels disposed two-dimensionally, for outputting a pixel signal having undergone photoelectric conversion;
a first analog-to-digital converter coupled with an output of the pixels of a first pixel column included in the plurality of the pixels, for converting a signal of the output into a digital signal;
an additional analog-to-digital converter coupled with the output of the pixels of the first pixel column;
a first cluster including a plurality of pixel columns including the first pixel column; and
a second cluster including a plurality of pixel columns including a second pixel column.

2. The imaging apparatus according to claim 1, further comprising:
a plurality of analog-to-digital converters of the first cluster, including the first analog-to-digital converter; and
a plurality of analog-to-digital converters of the second cluster, including a second analog-to-digital converter for converting an output signal of the pixels included in the second pixel column into a digital signal,
wherein the additional analog-to-digital converter is included in the second cluster; and
both the plurality of the analog-to-digital converters of the first cluster and the plurality of the analog-to-digital converters of the second cluster are located on an identical side of the plurality of the pixels disposed two-dimensionally, the analog-to-digital converters of the first cluster being coupled with an output of a plurality of the pixels included in the first cluster, the analog-to-digital converters of the second cluster being coupled with an output of a plurality of the pixels included in the second cluster.

3. The imaging apparatus according to claim 2, wherein the first cluster and the second cluster are adjacent to each other.

4. The imaging apparatus according to claim 1, further comprising:
a plurality of analog-to-digital converters including the first analog-to-digital converter; and
a plurality of analog-to-digital converters including a second analog-to-digital converter,
wherein the plurality of the pixel columns of the first cluster and the plurality of the pixel columns of the second cluster are located alternately, and
the plurality of the analog-to-digital converters included in the first cluster and the plurality of the analog-to-digital converters included in the second cluster are located respectively on different sides of the plurality of the pixels disposed two-dimensionally.

5. The imaging apparatus according to claim 2, further comprising a load, wherein the load is coupled with a wiring that couples the analog-to-digital converters with the pixels of the pixel columns with which no additional analog-to-digital converter is coupled.

6. The imaging apparatus according to claim 2, wherein the plurality of the pixel columns included in the first cluster has one of a different power line and a different ground line from those of the plurality of the pixel columns included in the second cluster.

7. The imaging apparatus according to claim 3, wherein the plurality of the pixel columns included in the first cluster has one of a different power line and a different ground line from those of the plurality of the pixel columns included in the second cluster.

8. The imaging apparatus according to claim 4, wherein the plurality of the pixel columns included in the first cluster has one of a different power line and a different ground line from those of the plurality of the pixel columns included in the second cluster.

9. The imaging apparatus according to claim 5, wherein the plurality of the pixel columns included in the first cluster has one of a different power line and a different ground line from those of the plurality of the pixel columns included in the second cluster.

10. The imaging apparatus according to claim 2,
wherein the plurality of the pixel columns included in the first cluster shares one of a power line and a ground line, and
the plurality of the pixel columns included in the second cluster shares one of a power line and a ground line.

11. The imaging apparatus according to claim 3,
wherein the plurality of the pixel columns included in the first cluster shares one of a power line and a ground line, and
the plurality of the pixel columns included in the second cluster shares one of a power line and a ground line.

12. The imaging apparatus according to claim 4,
wherein the plurality of the pixel columns included in the first cluster shares one of a power line and a ground line, and
the plurality of the pixel columns included in the second cluster shares one of a power line and a ground line.

13. The imaging apparatus according to claim 5,
wherein the plurality of the pixel columns included in the first cluster shares one of a power line and a ground line, and
the plurality of the pixel columns included in the second cluster shares one of a power line and a ground line.

14. The imaging apparatus according to claim 2, further comprising a digital processing circuit, wherein the digital processing circuit corrects a digital output of the plurality of the analog-to-digital converters included in the first cluster, based on a digital output of the additional analog-to-digital converter.

15. The imaging apparatus according to claim 3, further comprising a digital processing circuit, wherein the digital processing circuit corrects a digital output of the plurality of the analog-to-digital converters included in the first cluster, based on a digital output of the additional analog-to-digital converter.

16. The imaging apparatus according to claim 4, further comprising a digital processing circuit, wherein the digital processing circuit corrects a digital output of the plurality of the analog-to-digital converters included in the first cluster, based on a digital output of the additional analog-to-digital converter.

17. The imaging apparatus according to claim 5, further comprising a digital processing circuit, wherein the digital processing circuit corrects a digital output of the plurality of the analog-to-digital converters included in the first cluster, based on a digital output of the additional analog-to-digital converter.

18. The imaging apparatus according to claim 8,
wherein the digital processing circuit detects a difference between the first cluster and the second cluster, by using both the digital output of the first analog-to-digital converter and the digital output of the additional analog-to-digital converter; and
the circuit corrects the digital output of the plurality of the analog-to-digital converters included in the first cluster, based on the difference detected.

19. The imaging apparatus according to claim 9, further comprising a third cluster,
wherein the digital processing circuit detects a difference between the second cluster and the third cluster, by using both a digital output of the second analog-to-digital converter and a digital output of an additional analog-to-digital converter of the third cluster; and
the circuit corrects the digital output of the plurality of the analog-to-digital converters of the second cluster, based on the difference detected.

20. An imaging apparatus comprising:
a plurality of pixels disposed in a matrix and classified into an upper cluster and a lower cluster, a plurality of the pixels included in a first pixel column including:
a first group of the pixels classified under the upper cluster; and
a second group of the pixels classified under the lower cluster;
an upper analog-to-digital converter coupled with the pixels of the first group; and
a lower analog-to-digital converter coupled with the pixels of the second group,
wherein at least one of the pixels of the first group is coupled also with the lower analog-to-digital converter.
